(19) United States
(12) Patent Application Publication
(10) Pub. No.: US 2002/0024134 A1
(43) Pub. Date: Feb. 28, 2002

(54) Semiconductor device

(75) Inventors: Kiyoshi Arai, Chiyoda-ku (JP); Hideo Matsumoto, Chiyoda-ku (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, Chiyoda-ku (JP)

(21) Appl. No.: 09/796,518

(22) Filed: Mar. 2, 2001

(30) Foreign Application Priority Data
Aug. 28, 2000 (JP) 2000-257227

(51) Int. Cl. H01L 23/34

(52) U.S. Cl. 257/723

(57) ABSTRACT

A wiring pattern (26) or (27) and conductor wires (W1, W2) or (W3, W4) not relaying a wiring pattern (22) or (23) fed with an emitter current connect emitter electrodes of a plurality of IGBTs (3) connected in parallel with each other. Thus, oscillation appearing on the potential of a control electrode of the plurality of IGBTs (3) is suppressed.

### BACKGROUND OF THE INVENTION

1. Field of the Invention

The present invention relates to a semiconductor device suitable for controlling a large current, and more particularly, it relates to an improvement for suppressing oscillation appearing on the potential of a control electrode of a switching element.

2. Description of the Background Art

FIG. 16 is a plan sectional view showing a base portion of a conventional semiconductor device 150 forming the background of the present invention. This semiconductor device 150 is formed as a power module comprising a plurality of power semiconductor elements. As shown in FIG. 16, the semiconductor device 150 comprises a substrate 62 on its bottom potion. A plurality of wiring patterns 81 to 85 isolated from each other are arranged on the main surface of the substrate 62 in the form of islands. Two IGBTs 63 and two diodes 64 belonging to an upper arm 70 are arranged on the wiring pattern 81, while two IGBTs 63 and two diodes 64 belonging to a lower arm 71 are arranged on the wiring pattern 82.

The four IGBTs 63 and the four diodes 64 are formed as bare chips. Thus, collector electrodes of the two IGBTs 63 and cathodes of the two diodes 64 belonging to the upper arm 70 are electrically connected with each other through the wiring pattern 81. Similarly, collector electrodes of the two IGBTs 63 and cathodes of the two diodes 64 belonging to the lower arm 71 are electrically connected with each other through the wiring pattern 82.

A number of conductor wires 75 connect emitter electrodes of the two IGBTs 63 belonging to the upper arm 70 with the wiring pattern 82. A number of conductor wires 76 connect anodes of the two diodes 64 belonging to the upper arm 70 with the wiring pattern 82. Similarly, a number of conductor wires 75 connect emitter electrodes of the two IGBTs 63 belonging to the lower arm 71 with the wiring pattern 83. Further, a number of conductor wires 76 connect anodes of the two diodes 64 belonging to the lower arm 71 with the wiring pattern 83.

FIG. 16 omits illustration of the conductor wires 75 as to the upper arm 70 while omitting illustration of the conductor wires 76 as to the lower arm 71, in order to avoid complication.

Conductor wires 77 connect the wiring pattern 84 with gate electrodes of the two IGBTs 63 belonging to the upper arm 70. Similarly, conductor wires 77 connect the wiring pattern 85 with gate electrodes of the two IGBTs 63 belonging to the lower arm 71.

An external terminal CC supplied with a high power supply potential, an external terminal EE supplied with a low power supply potential, an external terminal OUT connected with a load and external terminals G1, G2, S1 and S2 connected with drive circuits are connected to the wiring patterns 81 to 85. FIG. 16 shows connection parts between the wiring patterns 81 to 85 and the external terminals CC, EE, OUT, G1, G2, S1 and S2 with hatching.

In the semiconductor device 150, as hereinabove described, the serially connected upper and lower arms 70 and 71 are interposed between the high power supply potential and the low power supply potential so that the two IGBTs 63 belonging to the upper arm 70 (and the lower arm 71) are turned on/off in response to a drive signal input in the external terminal G1 (and G2).

As shown in the example of the semiconductor device 150, a plurality of power switching elements are connected in parallel with each other in a power module having a large rated current of at least 100 A, for example, in order to share the large current.

When unexpected short-circuiting is caused on a load, however, a short-circuit current of about five to 10 times the rated current flows in the power module. In the power module comprising a plurality of power switching elements, the potential of a control electrode (gate electrode in an IGBT) of each switching element may oscillate when such a short-circuit current flows. Such a tendency is recognized that oscillation readily takes place as the rated current of the power module is increased.

Such oscillation may influence normal operation of an applied apparatus utilizing the power module, or cause noise. If the switching element is an IGBT, further, influence on a gate insulator film is also supposed.

### SUMMARY OF THE INVENTION

Thus, an object of the present invention is to provide a semiconductor device capable of suppressing oscillation appearing on the potential of a control electrode of a switching element.

According to a first aspect of the present invention, a semiconductor device comprises a substrate having a main surface, a first wiring pattern arranged on the main surface, a plurality of switching elements arranged on the first wiring pattern so that first main electrodes thereof are electrically connected with each other, a second wiring pattern arranged on the main surface, a plurality of first conductor wires having first ends connected to second main electrodes of the plurality of switching elements and second ends connected to the second wiring pattern, an external terminal connected to the second wiring pattern for electrically connecting the second main electrodes of the plurality of switching elements with the exterior through the second wiring pattern and a conductor electrically connecting the second main electrodes of the plurality of switching elements with each other without through the second wiring pattern.

In the semiconductor device according to the first aspect, the second main electrodes of the plurality of switching elements connected in parallel with each other are electrically connected with each other through the conductor not relaying the second wiring pattern, i.e., the conductor not fed with a main current, whereby the potentials of the second main electrodes are uniformized between the plurality of switching elements. Consequently, the potentials of control electrodes of the plurality of switching elements are inhibited from oscillation also when a load on the plurality of switching elements is short-circuited.

According to a second aspect of the present invention, the conductor includes a third wiring pattern arranged on the main surface isolatedly from the second wiring pattern and a plurality of second conductor wires having first ends connected to the second main electrodes of the plurality of switching elements and second ends connected to the third wiring pattern.

In the semiconductor device according to the second aspect, electrical connection between the second main electrodes of the plurality of switching elements is readily implemented through the third wiring pattern and the second conductor wires. Further, no wire cutting may be performed on the switching elements in a step of arranging the second conductor wires, to require no means for preventing damage of the switching elements.

According to a third aspect of the present invention, the second wiring pattern extends along the direction of arrangement of the plurality of switching elements, and the third wiring pattern extends along the direction of arrangement of the plurality of switching elements on the side opposite to the second wiring pattern through the plurality of switching elements.

In the semiconductor device according to the third aspect, the second and third wiring patterns are arranged on opposite sides of the plurality of switching elements and extend along the direction of arrangement of the plurality of switching elements, whereby the first and second conductor wires can be readily arranged without interfering with each other. Further, inductive coupling between the first and second conductor wires can be reduced thereby improving the effect of suppressing oscillation.

According to a fourth aspect of the present invention, the third wiring pattern is adjacent to the plurality of switching elements without through the remaining wiring patterns interposed therebetween.

In the semiconductor device according to the fourth aspect, the third wiring pattern is adjacent to the plurality of switching elements without the remaining wiring patterns interposed therebetween, whereby the second conductive wires can be set short. Thus, the inductance of the conductor electrically connecting the second main electrodes of the plurality of switching elements is reduced, whereby the effect of uniformizing the potentials of the second main electrodes can be improved.

According to a fifth aspect of the present invention, the third wiring pattern has a repetitive bent portion.

In the semiconductor device according to the fifth aspect, the third wiring pattern has the repetitive bent potion, whereby the inductance of the conductor electrically connecting the second main electrodes of the plurality of switching elements can be adjusted to a value optimum for suppressing oscillation.

According to a sixth aspect of the present invention, the conductor includes a third conductor wire directly connecting the second main electrodes of the plurality of switching elements with each other.

In the semiconductor device according to the sixth aspect, the third conductor wire directly connects the second main electrodes of the plurality of switching elements with each other, whereby steps of manufacturing the semiconductor device are simplified and the semiconductor device can be miniaturized.

According to a seventh aspect of the present invention, the second wiring pattern extends along the direction of arrangement of the plurality of switching elements, the plurality of first conductor wires are arranged in a direction substantially perpendicular to the direction of arrangement, and the third conductor wire is arranged along the direction of arrangement.

In the semiconductor device according to the seventh aspect, the first and third conductor wires are arranged to be substantially orthogonal to each other so that inductive coupling therebetween is suppressed, thereby improving the effect of suppressing oscillation.

According to an eighth aspect of the present invention, the third conductor wire is connected with the second main electrodes of the plurality of switching elements on portions farther from the second wiring pattern than the first ends of the plurality of first conductor wires.

In the semiconductor device according to the eighth aspect, the third conductor wire is connected to the second main electrodes of the plurality of switching elements on the portions farther from the second wiring pattern than the first ends of the plurality of first conductor wires, whereby inductive coupling between the first and third conductor wires is further suppressed thereby further improving the effect of suppressing oscillation. In addition, the first and second conductor wires can be readily arranged without interfering with each other.

According to a ninth aspect of the present invention, the semiconductor device further comprises a fourth wiring pattern arranged on the main surface, a plurality of fourth conductor wires having first ends connected to control electrodes of the plurality of switching elements and second ends connected to the fourth wiring pattern and a voltage clamping element having a first end connected to the third wiring pattern and a second end connected to the fourth wiring pattern.

In the semiconductor device according to the ninth aspect, the voltage clamping element is interposed between the control electrodes of the plurality of switching elements and the third wiring pattern. Even if the potentials of the control electrodes oscillate, therefor, amplitudes thereof are suppressed.

According to a tenth aspect of the present invention, a semiconductor device comprises a substrate having a main surface, a first wiring pattern arranged on the main surface, a plurality of switching elements arranged on the first wiring pattern so that first main electrodes thereof are electrically connected with each other, a second wiring pattern arranged on the main surface, a plurality of first conductor wires having first ends connected to second main electrodes of the plurality of switching elements and second ends connected to the second wiring pattern, an external terminal connected to the second wiring pattern for electrically connecting the second main electrodes of the plurality of switching elements with the exterior through the second wiring pattern and a voltage clamping element electrically connected between control electrodes and the second main electrodes of the plurality of switching elements.

In the semiconductor device according to the tenth aspect, the voltage clamping element is interposed between the control electrodes and the second main electrodes of the plurality of switching elements, thereby suppressing amplitudes of oscillation.

According to an eleventh aspect of the present invention, a semiconductor device comprises a substrate having a main surface, a first wiring pattern arranged on the main surface, a plurality of switching elements arranged on the first wiring pattern so that first main electrodes thereof are electrically connected with each other, a second wiring pattern arranged on the main surface to extend along the direction of arrangement of the plurality of switching elements, a plurality of first conductor wires having first ends connected to second main electrodes of the plurality of switching elements and second ends connected to the second wiring pattern, an external terminal connected to the second wiring pattern for electrically connecting the second main electrodes of the plurality of switching elements with the exterior through the second wiring pattern, a plurality of diodes, provided in the same number as the plurality of switching elements, arranged on the first wiring pattern so that first electrodes thereof are electrically connected with each other and arranged between the plurality of switching elements and the second wiring pattern to be adjacent to the plurality of switching elements in one-to-one correspondence, a plurality of second conductor wires having first ends connected to second electrodes of the plurality of diodes and second ends connected to the second wiring pattern and a plurality of third conductor wires having first ends connected to the second main electrodes of the plurality of switching elements, intermediate potions connected to the second electrodes of at least part of the plurality of diodes and second ends connected to the second wiring pattern thereby electrically connecting all second main electrodes of the plurality of switching elements with each other without through the second wiring pattern.

In the semiconductor device according to the eleventh aspect, the second main electrodes of the plurality of switching elements are electrically connected with each other through the third conductor wires and the second electrodes of the diodes without through the second wiring pattern. Thus, the potentials of the second main electrodes are uniformized between the plurality of switching elements, whereby the potentials of the control electrodes are inhibited from oscillation also when a load is short-circuited. Further, the second ends of the third conductor wires are connected to the second wiring pattern, whereby no wire cutting may be performed on the switching elements or on the diodes in a step of arranging the third conductor wires. Therefore, no means is required for preventing damage of the switching elements and the diodes in manufacturing steps.

According to a twelfth aspect of the present invention, the second wiring pattern extends along the direction of arrangement of the plurality of switching elements, the second wiring pattern is formed with a slit extending along the direction of arrangement so as to leave a coupling portion on the side of a first end of the direction of arrangement while as to leave no coupling portion on the side of a second end, the second ends of the plurality of first conductor wires are connected to the second wiring pattern on a first portion closer to the plurality of switching elements than the slit, and the external terminal is connected to the second wiring pattern on the coupling portion on the side of the first end, while the semiconductor device further comprises another external terminal connected to the second wiring pattern on the side of the second end in a second portion farther from the plurality of switching elements than the slit for electrically connecting the second main electrodes of the plurality of switching elements with the exterior through the second wiring pattern.

In the semiconductor device according to the twelfth aspect, the second wiring pattern extends along the direction of arrangement of the plurality of switching elements and has the slit extending along the direction of arrangement so as to leave the coupling portion on the side of the first end of the direction of arrangement while as to leave no coupling portion on the side of the second end, the second ends of the plurality of first conductor wires are connected to the first portion, the external terminal is connected on the coupling portion on the side of the first end, and the other external terminal is connected to the side of the second end of the second portion. When employing the other external terminal as a terminal supplying a reference potential for the potentials of the control electrodes, therefore, a main current is inhibited from abrupt increase, due to a feedback action resulting from the inductance of the first portion. Consequently, the potentials of the control electrodes are more effectively inhibited from oscillation.

According to a thirteenth aspect of the present invention, a semiconductor device comprises a substrate having a main surface, a first wiring pattern arranged on the main surface, a plurality of switching elements arranged on the first wiring pattern so that first main electrodes thereof are connected with each other, a second wiring pattern arranged on the main surface to extend along the direction of arrangement of the plurality of switching elements and formed with a slit extending along the direction of arrangement so as to leave a coupling portion on the side of a first end of the direction of arrangement while as to leave no coupling portion on the side of a second end, a plurality of first conductor wires having first ends connected to second main electrodes of the plurality of switching elements and second ends connected to the second wiring pattern on a first portion closer to the plurality of switching elements than the slit, an external terminal connected to the second wring pattern on the coupling portion on the side of the first end for electrically connecting the second main electrodes of the plurality of switching elements with the exterior through the second wiring pattern and another external terminal connected to the second wiring pattern on the side of the second end in a second portion farther from the plurality of switching elements than the slit for electrically connecting the second main electrodes of the plurality of switching elements with the exterior through the second wiring pattern.

In the semiconductor device according to the thirteenth aspect, the second wiring pattern extends along the direction of arrangement of the plurality of switching elements and has the slit extending along the direction of arrangement as to leave the coupling portion on the side of the first end of the direction of arrangement while as to leave no coupling portion on the side of the second end, the second ends of the plurality of first conductor wires are connected to the first portion, the external terminal is connected to the coupling portion on the side of the first end, and the other external terminal is connected to the side of the second end of the second portion. When employing the other external terminal as a terminal supplying a reference potential for the potentials of the control electrodes, therefore, a main current is inhibited from abrupt increase, due to a feedback action resulting from the inductance of the first portion. Consequently, the potentials of the control electrodes are more effectively inhibited from oscillation.

According to a fourteenth aspect of the present invention, the semiconductor device further comprises a fifth conductor wire having a first end connected to the first portion and a second end connected to the second portion.

The semiconductor device according to the fourteenth aspect comprises the fifth conductor connecting the first and second portions with each other, whereby the strength of the feedback action can be finely adjusted to be uniform among the individuals of the products by controlling the position for connecting the fifth conductor wire in the final stage of steps of manufacturing the semiconductor device.

According to a fifteenth aspect of the present invention, each of the plurality of switching elements is an insulated gate switching element.

In the semiconductor device according to the fifteenth aspect, the plurality of switching elements are inhibited from oscillation although each switching element is a readily oscillating insulated gate switching element, whereby the semiconductor device can be widely applied to apparatus controlling a large current through the advantage of the insulated gate switching element easy to control.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram of a semiconductor device according to an embodiment 1 of the present invention;

FIG. 2 is a perspective view showing the appearance of the semiconductor device according to the embodiment 1;

FIG. 3 is a plan sectional view of the semiconductor device according to the embodiment 1;

FIG. 4 is a plan sectional view of a semiconductor device according to an embodiment 2 of the present invention;

FIG. 5 is a plan sectional view of a semiconductor device according to an embodiment 3 of the present invention;

FIG. 6 is a plan sectional view of a semiconductor device according to an embodiment 4 of the present invention;

FIG. 7 is a plan sectional view of a semiconductor device according to an embodiment 5 of the present invention;

FIG. 8 is a circuit diagram showing part of the semiconductor device according to the embodiment 5;

FIG. 9 is a plan sectional view of a semiconductor device according to an embodiment 6 of the present invention;

FIG. 10 is a model diagram showing part of the semiconductor device according to the embodiment 6;

FIG. 11 is a circuit diagram showing part of the semiconductor device according to the embodiment 6;

FIG. 12 is a plan sectional view of a semiconductor device according to an embodiment 7 of the present invention;

FIGS. 13 and 14 are model diagrams showing part of the semiconductor device according to the embodiment 7;

FIG. 15 is a circuit diagram showing part of the semiconductor device according to the embodiment 7; and

FIG. 16 is a plan sectional view of a conventional semiconductor device.

### DESCRIPTION OF THE PREFERRED EMBODIMENTS

### Outline of Embodiments

As techniques of preventing such a phenomenon that a power module comprising a plurality of switching elements such as the semiconductor device 150 shown in FIG. 16 causes oscillation resulting from a short-circuit current or relaxing such oscillation, the inventor has supposed the following three approaches: (1) to uniformize reference potentials for the potentials of control electrodes (gate electrodes in IGBTs) of parallel-connected switching elements, i.e., the potentials of first main electrodes (emitter electrodes in IGBTs); (2) to provide an element absorbing oscillation; and (2) to reduce a short-circuit current.

When a short-circuit flows, increase rate (=dI/dt) of a main current (emitter current in an IGBT) exceeds increase in the main current I under normal switching operation. Due to such change in the main current, induced electromotive force V (=−L×dI/dt) results from internal inductance L parasitically present in the power module and is superposed on the potentials of the control electrodes. This induced electromotive force V is applied in a direction pulling up the potentials of the control electrodes, i.e., a direction increasing the main current I. When increase of the potentials of the control electrodes exceeds a certain limit, vibration is caused on the potentials of the control electrodes.

While the induced electromotive force V is applied to each of the plurality of parallel-connected switching elements, each switching element independently operates in a transient state. Due to characteristic difference slightly present between the plurality of switching elements, therefore, exchange of vibration is caused between the plurality of switching elements to act in a direction enlarging oscillation. In order to suppress enlargement of oscillation, therefore, it is effective to uniformize reference potentials between the plurality of switching elements.

In order to uniformize the reference potentials between the plurality of switching elements, it is effective to connect first main electrodes of the plurality of switching elements formed on semiconductor chips on positions as close as possible to each other with a conductor not influenced by the main current I. In a power module having such means, the induced electromotive force V acting between the respective switching elements due to the increase (=dI/dt) in the main current I upon flowing of a short-circuit current is automatically balanced, thereby enabling suppression or prevention of oscillation. This is the first approach.

In the second approach, a voltage clamping element is interposed between the control electrodes and the first main electrodes of the plurality of parallel-connected switching elements. Thus, also when oscillation takes place, the potentials of the control electrodes can be suppressed below a certain limit. In other words, the strength of oscillation can be relaxed. When the switching elements are insulated gate switching elements such as IGBTs, influence on gate insulator films can be prevented due to relaxation of the strength of oscillation.

In order to suppress oscillation, it is effective to reduce the induced electromotive force V applied to the control electrodes. However, the internal inductance L parasitically present in the power module is already reduced to a limit level in the current technique inclusive of the semiconductor device 150 shown in FIG. 16. Therefore, the increase (=dI/dt) in the current must be suppressed in order to reduce the induced electromotive force V. The increase (=dI/dt) in the current can be reduced by suppressing the potentials of the control electrodes of the plurality of switching elements low.

When a load is short-circuited, a large short-circuit current flows in a wiring pattern fed with the main current I. At this time, induced electromotive force is generated in the wiring pattern due to inductance specific to this portion. This induced electromotive force pulls up the potentials of the first main electrodes thereby pulling down the potentials of the control electrodes with reference to the first main electrodes and suppressing increase in the main current I in each switching element. This is the third approach.

Preferred embodiments of the present invention based on these three approaches are now described in detail. Embodiments 1 to 4 are based on the first approach, an embodiment 5 is based on the first and second approaches, and embodiments 6 and 7 are based on the first and third approaches respectively.

### Embodiment 1

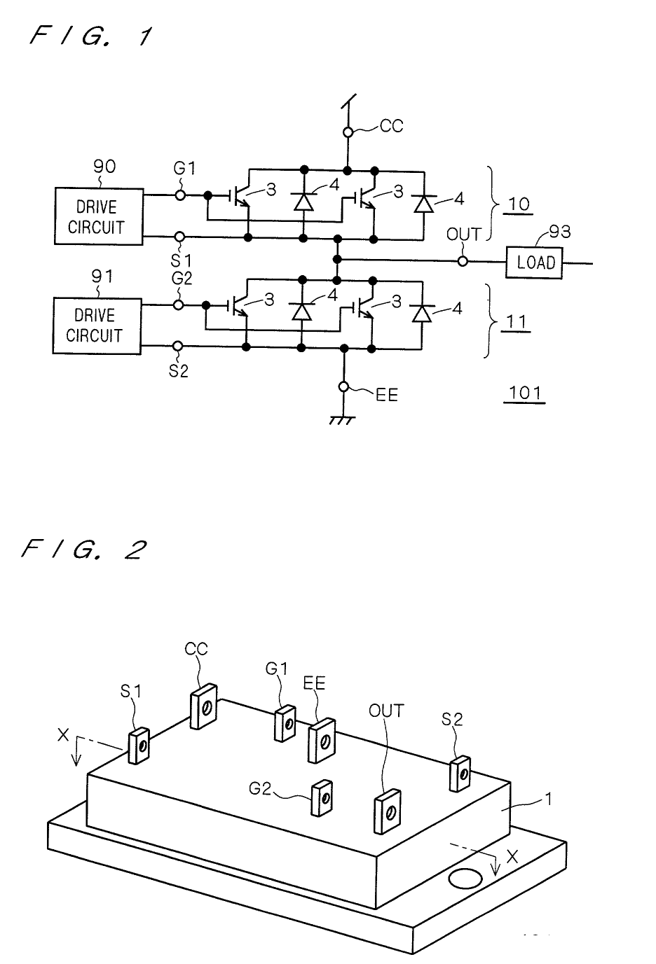

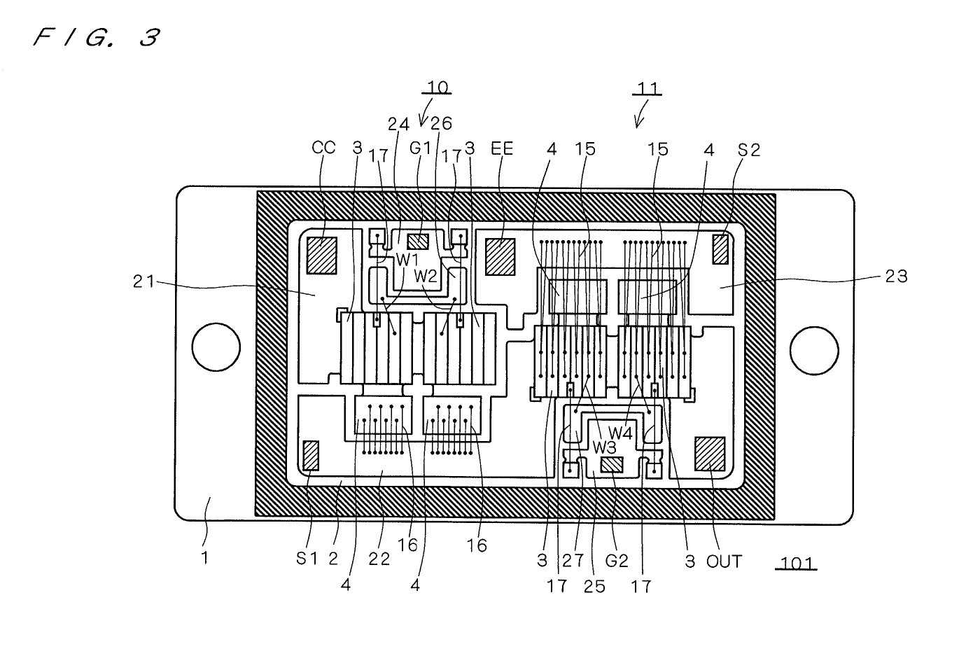

FIG. 1 is a circuit diagram of a semiconductor device 101 according to the embodiment 1 of the present invention. FIG. 2 is a perspective view showing the appearance of the semiconductor device 1 shown in FIG. 1, and FIG. 3 is a sectional view of the semiconductor device 101 taken along the line X-X in FIG. 2.

As shown in FIG. 1, the semiconductor device 101 comprises an upper arm 10 having two IGBTs 3 and two diodes 4 and a lower arm 11 similarly having two IGBTs 3 and two diodes 4. Power IGBTs are employed as the IGBTs 3, and power diodes are employed as the diodes 4. In other words, the semiconductor device 101 is formed as a power module comprising a plurality of power semiconductor elements.

In each of the upper and lower arms 10 and 11, emitter electrodes, collector electrodes and gate electrodes of the two IGBTs 3 are connected with each other. In other words, the two IGBTs 3 are connected in parallel with each other to function as a single IGBT together. The two diodes 4 are connected in parallel with the two IGBTs 3 in a direction circulating a forward current, to function as freewheel diodes. In other words, anodes of the diodes 4 are connected to the emitter electrodes of the IGBTs 3, and cathodes thereof are connected to the collector electrodes of the IGBTs 3.

The upper and lower arms 10 and 11 are serially connected with each other. The collector electrodes of the two IGBTs 3 of the upper arm 10 are connected to an external terminal CC, the gate electrodes are connected to an external terminal G1, and the emitter electrodes are connected to external terminals OUT and S1. The collector electrodes of the two IGBTs 3 of the lower arm 11 are connected to the external terminal OUT, the gate electrodes are connected to an external terminal G2, and the emitter electrodes are connected to external terminals EE and S2.

As shown in FIG. 2, these external terminals CC, G1, OUT, S1, G2 and S2 project outward from the upper surface of a case 1, thereby enabling connection to an external device (not shown). Referring again to FIG. 1, the external terminal CC is supplied with a high power supply potential (positive power supply potential in the example shown in FIG. 1), and the external terminal EE is supplied with a low power supply potential (ground potential in the example shown in FIG. 1). The external terminal OUT is connected with a load 93.

The external terminals G1 and S1 are connected with a drive circuit 90. The drive circuit 90 supplies a drive signal with reference to the potential of the external terminal S1 to the external terminal G1. The IGBTs 3 of the upper arm 10 are turned on/off in response to the drive signal input through the external terminal G1. Similarly, the external terminals G2 and S2 are connected with a drive circuit 91. The drive circuit 91 supplies a drive signal with reference to the potential of the external terminal S2 to the external terminal G2. The IGBTs 3 of the lower arm 11 are turned on/off in response to the drive signal input through the external terminal G2.

As shown in FIG. 3, the semiconductor device 101 comprises a substrate 2 on its bottom portion. A plurality of wiring patterns 21 to 27 isolated from each other are arranged on the main surface of the substrate 2 in the form of islands. The plurality of wiring patterns 21 to 27 are electrically insulated from each other. For such electrical insulation, the main surface of the substrate 2 may be an insulator, for example. Alternatively, an insulator may be interposed between the wiring patterns 21 to 27 and the substrate 2. The two IGBTs 3 and the two diodes 4 belonging to the upper arm 10 are arranged on the wiring pattern 21, and the two IGBTs 3 and the two diodes 4 belonging to the lower arm 11 are arranged on the wiring pattern 22.

The four IGBTs 3 and the four diodes 4 are formed as bare chips. Thus, the collector electrodes of the two IGBTs 3 and the cathodes of the two diodes 4 belonging to the upper arm 10 are electrically connected with each other through the wiring pattern 21. Similarly, the collector electrodes of the two IGBTs 3 and the cathodes of the two diodes 4 belonging to the lower arm 11 are electrically connected with each other through the wiring pattern 22.

The two diodes 4 and the two IGBTs 3 parallel-connected with each other are arranged to be adjacent to each other in one-to-one correspondence. In other words, arrangement is so performed that each diode 4 is adjacent to each IGBT 3. Thus, resistance and inductance between the diodes 4 and the IGBTs 3 are reduced and a protecting function of the diodes 4 serving as freewheel diodes for the IGBTs 3 is improved.

The external terminal CC is connected to the wiring pattern 21. In other words, the external terminal CC is electrically connected to the collector electrodes of the two IGBTs 3 belonging to the upper arm 10 and the cathodes of the two diodes 4 through the wiring pattern 21. Similarly, the external terminal OUT is connected to the wiring pattern 22. In other words, the external terminal OUT is electrically connected to the collector electrodes of the two IGBTs 3 belonging to the lower arm 11 and the cathodes of the two diodes 4 through the wiring pattern 22. FIG. 3 (and the following figures) shows connection parts between the wiring patterns 21 and 22 and the external terminals CC and OUT with hatching.

A number of conductor wires 15 connect the emitter electrodes of the two IGBTs 3 belonging to the upper arm 10 with the wiring pattern 22. A number of conductor wires 16 connect the anodes of the two diodes 4 belonging to the upper arm 10 with the wiring pattern 22. Similarly, a number of conductor wires 15 connect the emitter electrodes of the two IGBTs 3 belonging to the lower arm 11 with the wiring pattern 23. A number of conductor wires 16 connect the anodes of the two diodes 4 belonging to the lower arm 11 with the wiring pattern 23. The conductor wires 15 and 16 and conductor wires described later are formed by aluminum wires, for example.

FIG. 3 (and the following figures) omits illustration of the conductor wires 15 as to the upper arm 10 while omitting illustration of the conductor wires 16 as to the lower arm 11, in order to avoid complication.

The wiring pattern 22 extends along the direction of arrangement of the two IGBTs 3 belonging to the upper arm 10, and the wiring pattern 23 extends along the direction of arrangement of the two IGBTs 3 belonging to the lower arm 11. In each of the upper and lower arms 10 and 11, the conductor wires 15 connecting the emitter electrodes of the two parallel-connected IGBTs 3 with the wiring pattern 22 (or 23) are arranged in a direction substantially orthogonal to the direction of arrangement of the two IGBTs 3, to be minimized in length.

Similarly, the conductor wires 16 connecting the anodes of the parallel-connected two diodes 4 with the wiring pattern 22 (or 23) are arranged in a direction substantially orthogonal to the direction of arrangement of the two IGBTs 3, to be minimized in length. Consequently, the emitter electrodes of the two parallel-connected IGBTs 3 and the anodes of the two diodes 4 are connected to the wiring pattern 22 (or 23) through low resistance and low inductance.

The wiring pattern 22 is connected with the external terminal S1 in addition to the external terminal OUT, and the wiring pattern 23 is connected with the external terminals EE and S2. Thus, the emitter electrodes of the two IGBTs 3 and the anodes of the two diodes 4 belonging to the upper arm 10 are electrically connected with both of the external terminals OUT and S1 through the conductor wires 15 and 16 and the wiring pattern 22. Similarly, the emitter electrodes of the two IGBTs 3 and the anodes of the two diodes 4 belonging to the lower arm 11 are electrically connected with both of the external terminals EE and S2 through the conductor wires 15 and 16 and the wiring pattern 23.

The wiring pattern 24 is connected with the external terminal G1, and conductor wires 17 connect the wiring pattern 24 with the gate electrodes of the two IGBTs 3 belonging to the upper arm 10. In other words, the external terminal G1 and the gate electrodes of the IGBTs 3 are electrically connected with each other through the conductor wires 17 and the wiring pattern 24. Similarly, the wiring pattern 25 is connected with the external terminal G2, and conductor wires 17 connect the wiring pattern 25 with the gate electrodes of the two IGBTs 3 belonging to the lower arm 11. In other words, the external terminal G2 and the gate electrodes of the IGBTs 3 are electrically connected with each other through the conductor wires 17 and the wiring pattern 25.

Conductor wires W1 and W2 connect the wiring pattern 26 with the emitter electrodes of the two IGBTs 3 belonging to the upper arm 10. Thus, the emitter electrodes of the two IGBTs 3 belonging to the upper arm 10 are electrically connected with each other through the conductor wires W1 and W2 and the wiring pattern 26, which are paths not relaying the wiring pattern 22 and not fed with an emitter current flowing through the external terminal OUT. Consequently, the emitter potentials of the two IGBTs 3 belonging to the upper arm 10 are so uniformized that the potentials of the gate electrodes of the two IGBTs 3 are inhibited from oscillation also when the load 93 is short-circuited.

Similarly, conductor wires W3 and W4 connect the wiring pattern 27 with the emitter electrodes of the two IGBTs 3 belonging to the lower arm 11. Thus, the emitter electrodes of the two IGBTs 3 belonging to the lower arm 11 are electrically connected with each other through the conductor wires W3 and W4 and the wiring pattern 27, which are paths not relaying the wiring pattern 23 and not fed with an emitter current flowing through the external terminal EE. Consequently, the emitter potentials of the two IGBTs 3 belonging to the lower arm 11 are so uniformized that the potentials of the gate electrodes of the two IGBTs 3 are inhibited from oscillation also when the load 93 is short-circuited.

Connection between the emitter electrodes of the two IGBTs 3 for uniformizing the emitter potentials is readily implemented by connecting the emitter electrodes with the wiring pattern 26 (or 27) through the conductor wires W1 and W2 (or W3 and W4). In other words, manufacturing steps are advantageously simplified. Further, first ends of the conductor wires W1 and W2 (or W3 and W4) are connected to the wiring pattern 26 (or 27), whereby no wire cutting may be performed on the IGBTs 3 in a step of arranging the conductor wires W1 and W2 (or W3 and W4). Thus, the conductor wires W1 and W2 (or W3 and W4) can be readily arranged without requiring specific means for preventing damage of the IGBTs 3.

Further, the wiring pattern 22 extends along the direction of arrangement of the two IGBTs 3 belonging to the upper arm 10 and the wiring pattern 26 also extends along the direction of arrangement of the IGBTs 3 on the opposite side of the wiring paten 22 through the IGBTs 3. Thus, the conductor wires W1 and W2 can be readily arranged without interfering with the conductor wires 15. In addition, inductive coupling between the conductor wires 15 and the conductor wires W1 and W2 can be reduced, thereby improving the effect of suppressing oscillation.

Similarly, the wiring pattern 23 extends along the direction of arrangement of the two IGBTs 3 belonging to the lower arm 11 and the wiring pattern 27 also extends along the direction of arrangement of the IGBTs 3 on the opposite side of the wiring pattern 23 through the IGBTs 3. Therefore, an effect similar to that described above in relation to the upper arm 10 can be attained also as to the lower arm 11.

In each of the upper and lower arms 10 and 11, further, the two diodes 4 are arranged between the two IGBTs 3 and the wiring pattern 22 (or 23), whereby the conductor wires W1 and W2 (or W3 and W4) can be readily arranged without interfering with the conductor wires 16 connecting the anodes of the two diodes 4 with the wiring pattern 22 (or 23) either.

The wiring pattern 26 is adjacent to the two IGBTs 3 belonging to the upper arm 10 without the remaining wiring patterns interposed therebetween. Therefore, the conductor wires W1 and W2 can be set short. Thus, inductance of the paths electrically connecting the emitter electrodes of the two IGBTs 3 belonging to the upper arm 10 with each other is reduced, whereby the effect of uniformizing the potentials of the emitter electrodes can be further improved. Similarly, the wiring pattern 27 is adjacent to the two IGBTs 3 belonging to the lower arm 11 without through the remaining wiring patterns interposed therebetween. Also as to the lower arm 11, therefore, an effect similar to that described above in relation to the upper arm 10 can be attained.

While two IGBTs 3 and two diodes 4 are connected in parallel with each other in FIGS. 1 to 3, three or more IGBTs 3 and three or more diodes 4 may alternatively be connected in parallel with each other.

### Embodiment 2

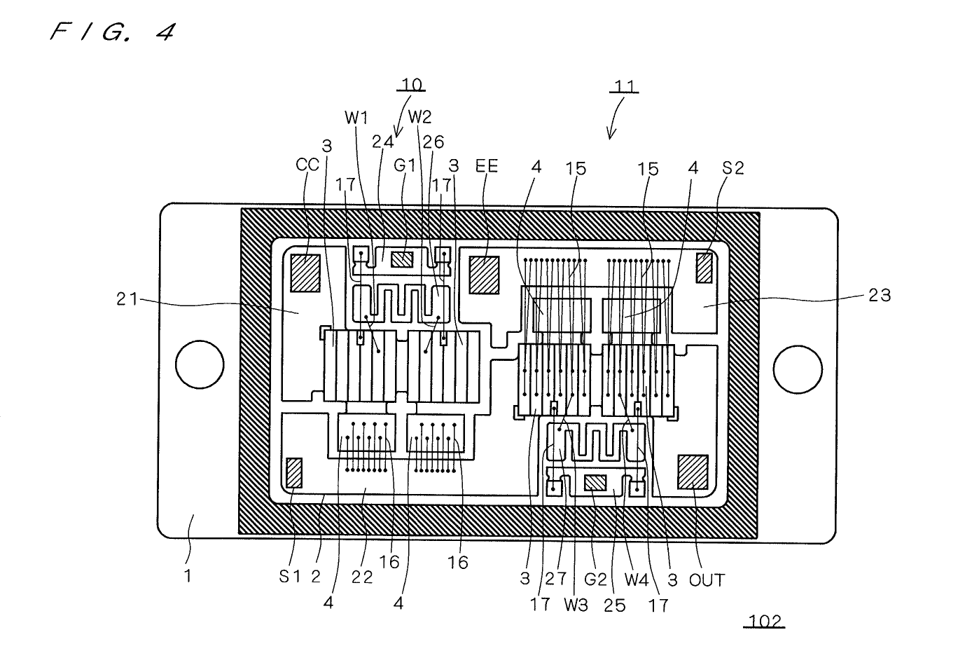

FIG. 4 is a plan sectional view of a semiconductor device 102 according to the embodiment 2 of the present invention. A circuit diagram and a perspective view of the appearance of the semiconductor device 102 are identical to FIGS. 1 and 2 showing the embodiment 1 respectively, and FIG. 4 is a sectional view of the semiconductor device 102, corresponding to the sectional view of the semiconductor device 101 taken along the line X-X in FIG. 2. In the following figures, parts identical or corresponding to (having the same functions as) those of the semiconductor device 101 shown in FIGS. 1 to 3 are denoted by the same reference numerals, to omit redundant description.

The semiconductor device 102 is characteristically different from the semiconductor device 101 shown in FIG. 3 in that each of wiring patterns 26 and 27 has a repetitive bent portion. It has been confirmed by an experiment that an optimum value for suppressing oscillation is present in the inductance of a path connecting emitter electrodes of two IGBTs 3 connected in parallel with each other without through a wiring pattern 22 (or 23). In the semiconductor device 102, each of the wiring patterns 26 and 27 has the repetitive bent portion, whereby the inductance of a path electrically connecting emitter electrodes of two parallel-connected IGBTs 3 can be freely controlled by changing positions for connecting conductor wires W1 to W4. Thus, the inductance of each of the wiring patterns 26 and 27 can be finely adjusted to the optimum value in the final stage of steps of manufacturing the semiconductor device 102.

While two IGBTs 3 and two diodes 4 are parallel-connected with each other in FIG. 3, three or more IGBTs 3 and three or more diodes 4 may alternatively be connected in parallel with each other.

### Embodiment 3

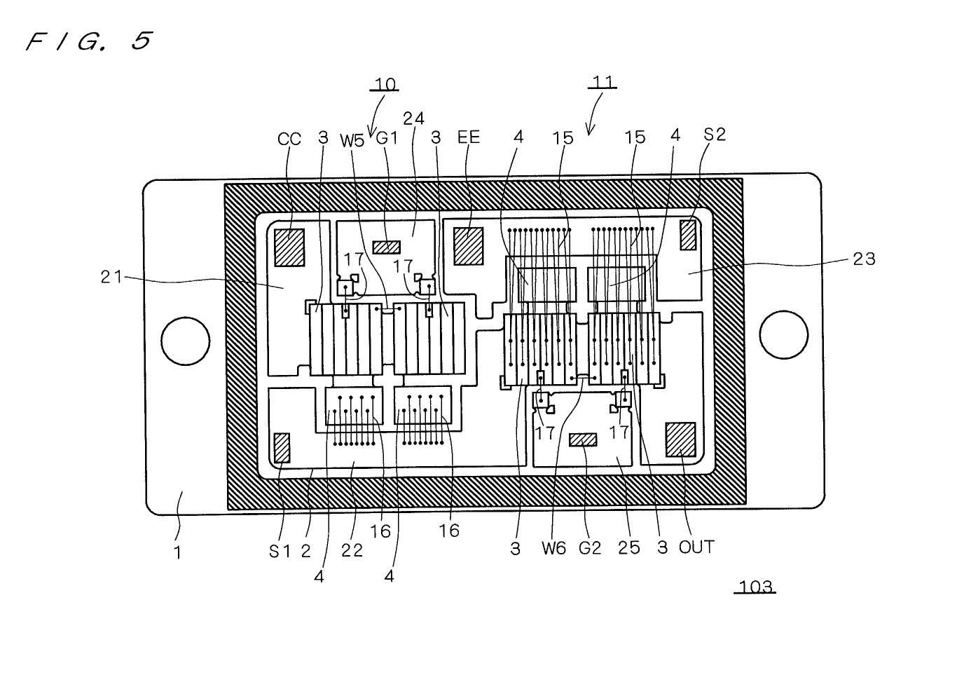

FIG. 5 is a plan sectional view of a semiconductor device 103 according to the embodiment 3 of the present invention. A circuit diagram and a perspective view of the appearance of the semiconductor device 103 are identical to FIGS. 1 and 2 showing the embodiment 1 respectively, and FIG. 5 is a sectional view of the semiconductor device 103, corresponding to the sectional view of the semiconductor device 101 taken along the line X-X in FIG. 2.

The semiconductor device 103 is characteristically different from the semiconductor device 101 shown in FIG. 3 in a point that neither wiring patterns 26 and 27 nor conductor wires W1 to W4 are provided but a conductor wire W5 (or W6) directly connects emitter electrodes of two parallel-connected IGBTs 3 with each other. Since no wiring patterns 26 and 27 are required, manufacturing steps are simplified and the area of a substrate 2 can be reduced for miniaturizing the semiconductor device 103.

As shown in FIG. 5, the conductor wire W5 (or W6) is arranged along the direction of arrangement of the two parallel-connected IGBTs 3 in each of upper and lower arms 10 and 11. Consequently, the conductor wire W5 (or W6) is substantially orthogonal to conductor wires 15 connecting the two parallel-connected IGBTs 3 with a wiring pattern 22 (or 23). Thus, inductive coupling between the conductor wires 15 and the conductor wire W5 (or W6) is suppressed low for further improving an effect of suppressing oscillation.

In each of the upper and lower arms 10 and 11, further, the conductor wire W5 (or W6) is connected to the emitter electrodes of the two IGBTs 3 on a portion farther from the wiring pattern 23 (or 23) than an end of the conductor wire 15. Thus, inductive coupling between the conductor wires 15 and the conductor wire W5 (or W6) is further suppressed lower thereby further improving the effect of suppressing oscillation. In addition, the conductor wires 15 and the conductor wire W5 (or W6) can be readily arranged without interfering with each other.

While two IGBTs 3 and two diodes 4 are connected in parallel with each other in FIG. 5, three or more IGBTs 3 and three or more diodes 4 may alternatively be connected in parallel with each other. In this case, the emitter electrodes may be individually connected with each other through a conductor wire between two adjacent ones of the plurality of parallel-connected IGBTs 3, or three or more portions, including an intermediate portion, of the conductor wire may be connected to the emitter electrodes thereby connecting emitter electrodes of three or more IGBTs 3 through a single conductor wire.

### Embodiment 4

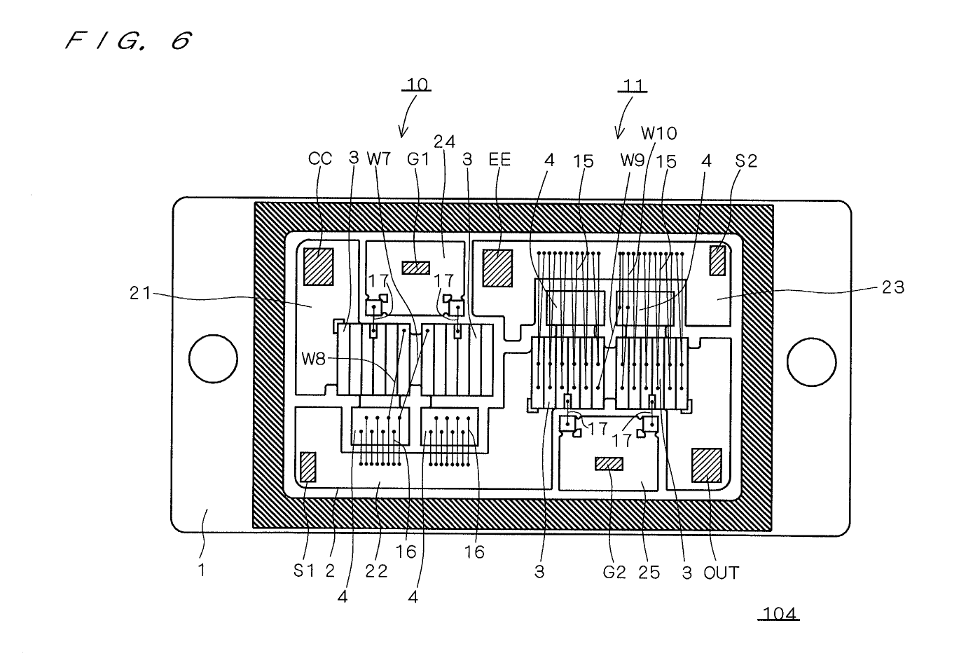

FIG. 6 is a plan sectional view of a semiconductor device 104 according to the embodiment 4 of the present invention. A circuit diagram and a perspective view of the appearance of the semiconductor device 104 are identical to FIGS. 1 and 2 showing the embodiment 1 respectively, and FIG. 6 is a sectional view of the semiconductor device 104, corresponding to the sectional view of the semiconductor device 101 taken along the line X-X in FIG. 2.

The semiconductor device 104 is characteristically different from the semiconductor device 101 shown in FIG. 3 in a point that neither wiring patterns 26 and 27 nor conductor wires W1 to W4 are provided but conductor wires W7 and W8 (or W9 and W10) connect emitter electrodes of two parallel-connected IGBTs 3 to an anode of one of two diodes 4 and a wiring pattern 22 (or 23). In other words, first ends of the conductor wires W7 and W8 (or W9 and W10) are connected to the emitter electrodes of the two parallel-connected IGBTs 3, intermediate portions are connected to the anode of one of the two diodes 4, and second ends are connected to the wiring pattern 22 (or 23).

Therefore, the emitter electrodes of the two parallel-connected IGBTs 3 are electrically connected with each other through the conductor wire W7 (or W9), the anode of the diode 4 and the conductor wire W8 (or W10) without through the wiring pattern 22 (or 23) fed with an emitter current. Consequently, the potentials of the emitter electrodes of the two parallel-connected IGBTs 3 are uniformized for attaining an effect of suppressing oscillation, similarly to the semiconductor device 101 (FIG. 3).

Further, second ends of the conductor wires W7 and W8 (or W9 and W10) are connected to a second wiring pattern, whereby no wire cutting may be performed on any of the IGBTs 3 and the diodes 4 in a step of arranging the conductor wires W7 and W8 (or W9 and W10). Therefore, no means for preventing damage of the IGBTs 3 and the diodes 4 may be required in manufacturing steps. In other words, the manufacturing steps can advantageously be simplified.

While two IGBTs 3 and two diodes 4 are connected in parallel with each other in FIG. 6, three or more IGBTs 3 and three or more diodes 4 may alternatively be parallel-connected. In this case, a plurality of conductor wires are arranged so that the emitter electrodes of all IGBTs 3 are electrically connected through the anode(s) of a single or a plurality of diodes 4 and a plurality of conductor wires without through the wiring pattern 22 (or 23). Also in this case, first ends of the conductor wires are connected to the emitter electrodes of the IGBTs 3, intermediate potions are connected to the anodes of the diodes 4 and second ends are connected to the wiring pattern 22 (or 23). While the first end of at least one conductor wire is connected to all of the plurality of IGBTs 3, it is possible to employ such a configuration that the intermediate portions of the conductor wires are connected to only part of the plurality of diodes 4.

### Embodiment 5

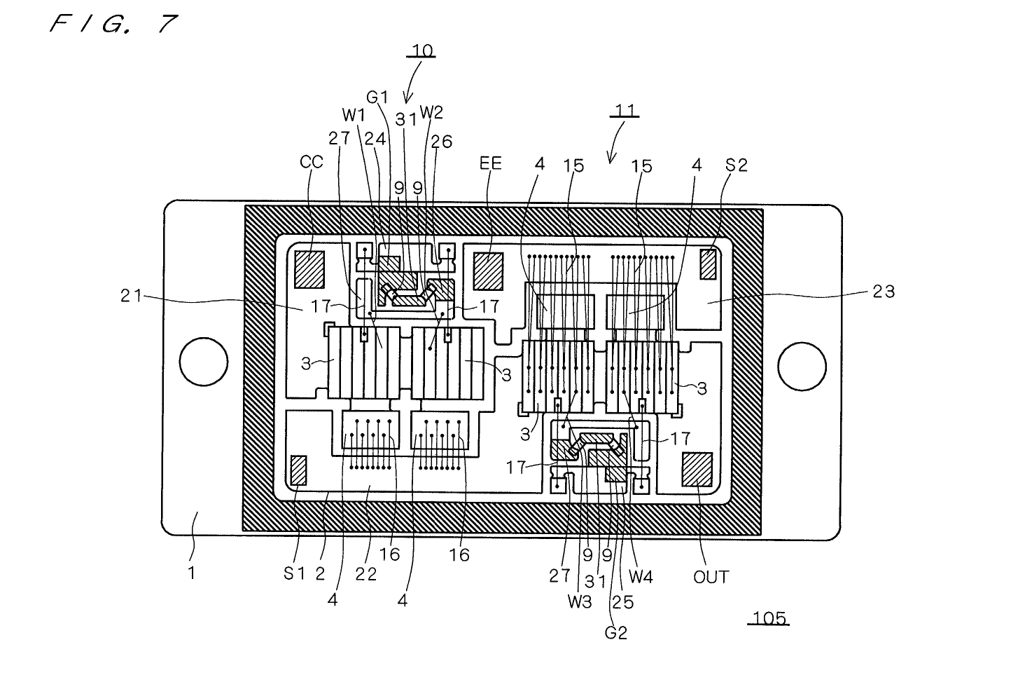

FIG. 7 is a plan sectional view of a semiconductor device 105 according to the embodiment 5 of the present invention. FIG. 8 is a circuit diagram o a part of the semiconductor device 105. A perspective view of the appearance of the semiconductor device 105 is identical to FIG. 2 showing the embodiment 1, and FIG. 7 is a sectional view of the semiconductor device 105, corresponding to the sectional view of the semiconductor device 101 taken along the line X-X in FIG. 2.

The semiconductor device 105 is characteristically different from the semiconductor device 101 shown in FIG. 3 in a point that two Zener diodes 9 serially connected with each other so that the direction of a forward current is reversed are interposed between a wiring pattern 24 (or 25) and a wiring pattern 26 (or 27). The two Zener diodes 9 are connected with each other through a wiring pattern 31 arranged on a substrate 2. The two serially connected Zener diodes 9 form a voltage clamping element 30.

The voltage clamping element 30 prevents the potential difference between gate electrodes and emitter electrodes of two parallel-connected IGBTs 3 from increasing beyond a certain limit. Also when oscillation takes place by any chance, therefore, its amplitude is suppressed not to exceed a certain limit.

While two IGBTs 3 and two diodes 4 are connected in parallel with each other in the example shown in FIG. 7, three or more IGBTs 3 and three or more diodes 4 may alternatively be connected in parallel with each other. While the clamping element 30 is provided on the semiconductor device 101 of FIG. 3 in FIG. 7, it is also possible to provide the clamping element 30 on the semiconductor device 102 of FIG. 4.

The clamping element 30 may alternatively be electrically connected between emitter electrodes and gate electrodes of a plurality of parallel-connected IGBTs 3 without providing the wiring pattern 26 (or 27) and conductor wires W1 and W2 (or W3 ad W4). For example, the clamping element 30 may be connected between a wiring pattern 22 (or 23) and the wiring pattern 24 (or 25). Although occurrence of oscillation cannot be suppressed in this mode, it is possible to suppress the amplitude of the occurring oscillation below a certain limit.

### Embodiment 6

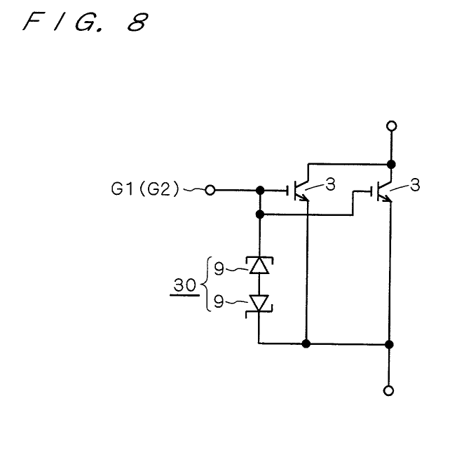

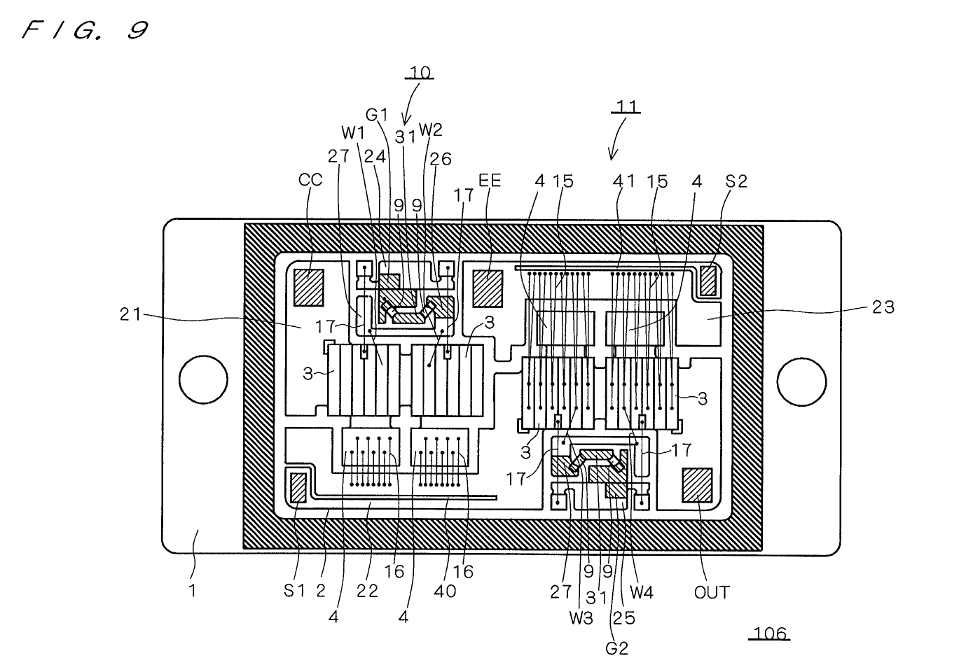

FIG. 9 is a plan sectional view of a semiconductor device 106 according to the embodiment 6 of the present invention. A perspective view of the appearance of the semiconductor device 106 is identical to FIG. 2 showing the embodiment 1, and FIG. 9 is a sectional view of the semiconductor device 106, corresponding to the sectional view of the semiconductor device 101 taken along the line X-X in FIG. 2.

The semiconductor device 106 is characteristically different from the semiconductor device 105 shown in FIG. 7 in that a wiring pattern 22 (or 23) extending along the direction of arrangement of two parallel-connected IGBTs 3 is formed with a slit 40 (or 41). The slit 40 (or 41) extends along the aforementioned direction of arrangement for leaving a coupling portion on the side of a first end of the aforementioned direction of arrangement while leaving no coupling portion on the side of a second end. In other words, the slit 40 (or 41) extends from the side of the aforementioned second end toward the side of the aforementioned first end for leaving the coupling portion on the side of the first end.

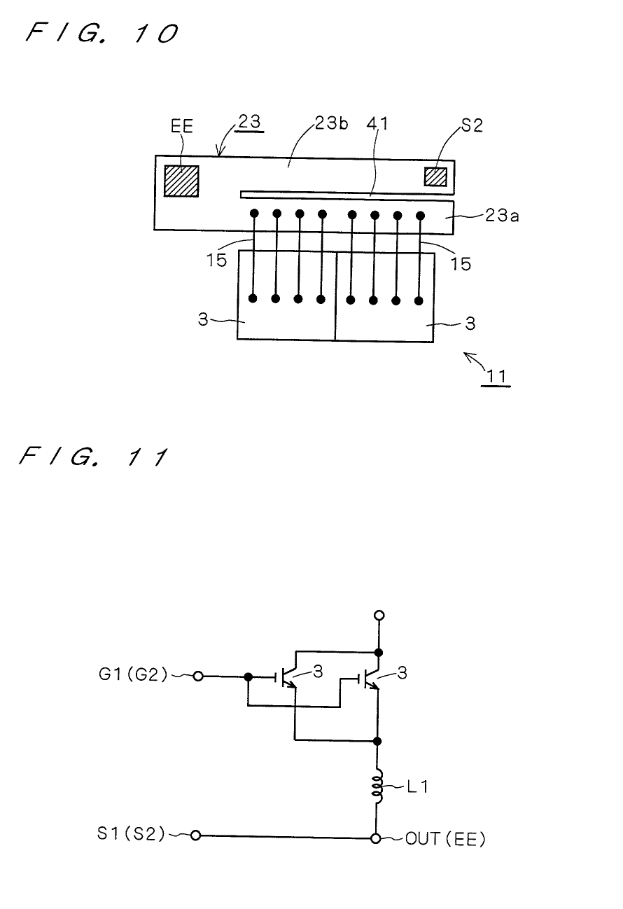

As FIG. 10 typically shows an exemplary wiring pattern 23, conductor wires 15 (and 16) are connected to a first portion 23a, closer to the two IGBTs 3 than the slit 40 (41), of the wiring pattern 22 (or 23). An external terminal OUT (or EE) is connected to the coupling portion on the side of the aforementioned first end of the wiring pattern 22 (or 23). Further, an external terminal S1 (or S2) is connected to the side of the aforementioned second end of a second portion 23b, farther from the two IGBTs 3 than the slit 40 (41), of the wiring pattern 22 (or 23). Therefore, a circuit diagram of FIG. 11 shows the relation among the two parallel-connected IGBTs 3, the external terminal OUT (or EE) and the external terminal S1 (S2).

An emitter current passes through the first portion 23a and flows to the external terminal OUT (or EE). When the emitter current abruptly increases due to short-circuiting of a load 93 or the like, therefore, counter electromotive force is generated between the emitter electrodes of the IGBTs 3 and the external terminal OUT (or EE) due to inductance L1 of the first portion 23a. In other words, the potentials of the emitter electrodes of the IGBTs 3 with reference to the potential of the external terminal OUT (or EE) increase. However, the potential of the external terminal S1 (or S2) remains equivalent to the potential of the external terminal OUT (or EE), and hence a gate voltage applied across the gate electrodes and the emitter electrodes of the IGBTs 3 is pulled down by the increased potentials of the emitter electrodes. Consequently, the emitter current is inhibited from increasing and an effect of suppressing oscillation is further improved.

While two IGBTs 3 and two diodes 4 are connected in parallel with each other in FIG. 9, three or more IGBTs 3 and three or more diodes 4 may alternatively be connected in parallel with each other. While the slits 40 and 41 are formed on the semiconductor device 105 of FIG. 7 in FIG. 9, it is also possible to provide the slits 40 and 41 on the semiconductor devices 101 to 104, for similarly improving the effect of suppressing oscillation.

The slit 40 (or 41) may be provided on the wiring pattern 22 (or 23) without providing a wiring pattern 26 (or 27) and conductor wires W1 and W2 (or W3 and W4) and without providing conductor wires W5 and W6. The effect of suppressing oscillation is suitably attained also in this configuration.

### Embodiment 7

FIG. 12 is a plan sectional view of a semiconductor device 107 according to the embodiment 7 of the present invention. A perspective view of the appearance of the semiconductor device 107 is identical to FIG. 2 showing the embodiment 1, and FIG. 12 is a sectional view of the semiconductor device 107, corresponding to the sectional view of the semiconductor device 101 taken along the line X-X in FIG. 2.

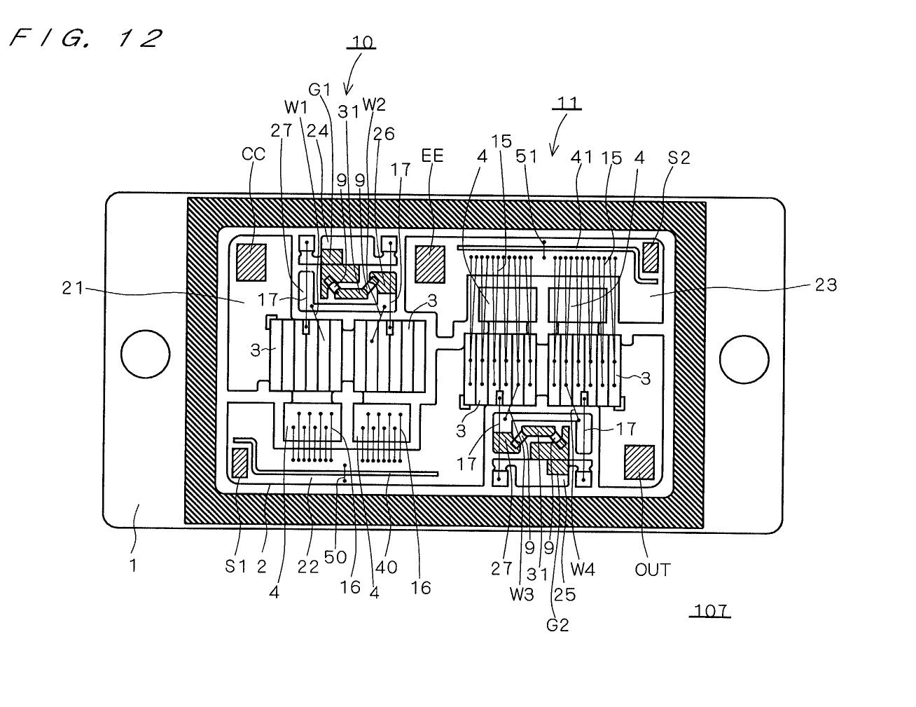

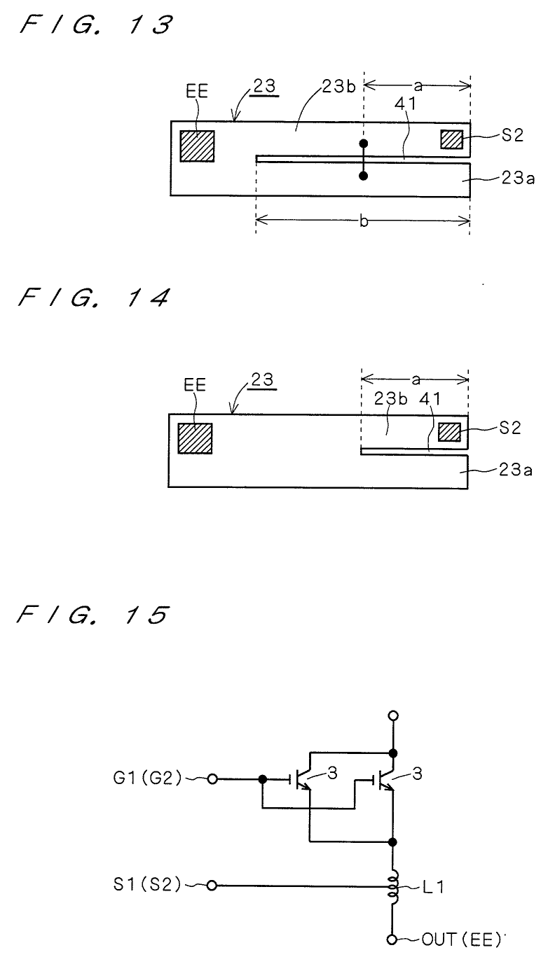

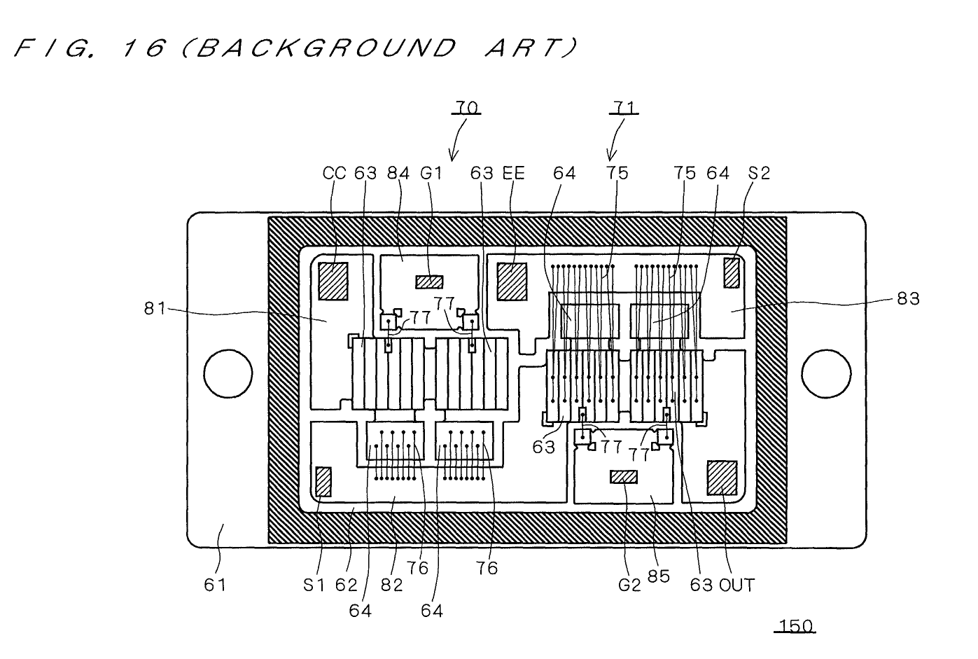

The semiconductor device 107 is characteristically different from the semiconductor device 106 of FIG. 9 in a point that a conductor wire 50 (or 51) connects a first portion 23a and a second portion 23b opposed to each other through a slit 40 (or 41) formed on a wiring pattern 22 (or 23). As FIG. 13 typically shows an exemplary wiring pattern 23, arrangement of the conductor wire 51 on a position of a distance a from an opening end of the slit 41 is substantially equivalent to that the depth b of the slit 41 is changed to a depth α identical to the distance α as shown in FIG. 14 in the relation between the potentials of external terminals EE and S2. This also applies to the conductor wire 50 set on the wiring pattern 22. When the conductor wire 50 (or 51) is arranged, therefore, a circuit diagram of FIG. 15 shows the relation among the two parallel-connected IGBTs 3, an external terminal OUT (or EE) and an external terminal S1 (or S2).

In other words, the potential of the external terminal S1 (or S2) can be freely controlled between the potentials of the emitter electrodes of the IGBTs 3 and the potential of the external terminal OUT (or EE) by changing the position for arranging the conductor wire 50 (or 51). Thus, it is possible to finely adjust individuals of mass-produced semiconductor devices 107 in the final stage of manufacturing steps so that the characteristics thereof are uniform.

### Modifications

(1) While the semiconductor device comprises a plurality of IGBTs in each of the aforementioned embodiments, the present invention is widely applicable to a semiconductor device comprising a plurality of switching elements having pairs of main electrodes fed with a main current (e.g., an emitter current, a drain current or the like) and control electrodes receiving a drive signal and controlling the main current in response thereto. The switching elements may be MOSFETs or bipolar transistors, for example.

Each of the semiconductor devices 101 to 107 according to the embodiments can be widely utilized for an applied apparatus controlling a large current through such advantages of insulated gate switching elements e.g. IGBTs that the same are easy to control although the same are naturally easy to cause oscillation and oscillation thereof can be suppressed. Further, insulated gate switching elements have high necessity for protection of gate insulator films, and hence the present invention is particularly useful for the device having insulated gate switching elements also in this sense.

(2) When some conductor electrically conducting emitter electrodes (generally main electrodes) of a plurality of IGBTs (generally a plurality of switching elements) without through a wiring pattern 22 (or 23) fed with an emitter current (generally a main current) is provided in general, uniformity of the potentials of emitter electrodes (generally main electrodes) can be improved thereby suppressing oscillation. The wiring pattern 26 (or 27) and the conductor wires W1 and W2 (or W3 and W4) correspond to the conductor in each of the semiconductor devices 101 and 102, while the conductor wire W5 (or W6) corresponds to the conductor in the semiconductor device 103.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a substrate having a main surface;
a first wiring pattern arranged on said main surface;
a plurality of switching elements arranged on said first wiring pattern so that first main electrodes thereof are electrically connected with each other;
a second wiring pattern arranged on said main surface;
a plurality of first conductor wires having first ends connected to second main electrodes of said plurality of switching elements and second ends connected to said second wiring pattern;
an external terminal connected to said second wiring pattern for electrically connecting said second main electrodes of said plurality of switching elements with the exterior through said second wiring pattern; and
a conductor electrically connecting said second main electrodes of said plurality of switching elements with each other without through said second wiring pattern.

2. The semiconductor device according to claim 1, wherein
said conductor includes:
a third wiring pattern arranged on said main surface isolatedly from said second wiring pattern, and
a plurality of second conductor wires having first ends connected to said second main electrodes of said plurality of switching elements and second ends connected to said third wiring pattern.

3. The semiconductor device according to claim 2, wherein
said second wiring pattern extends along the direction of arrangement of said plurality of switching elements, and
said third wiring pattern extends along the direction of arrangement of said plurality of switching elements on the side opposite to said second wiring pattern through said plurality of switching elements.

4. The semiconductor device according to claim 3, wherein
said third wiring pattern is adjacent to said plurality of switching elements without the remaining wiring patterns interposed therebetween.

5. The semiconductor device according to claim 2, wherein
said third wiring pattern has a repetitive bent portion.

6. The semiconductor device according to claim 1, wherein
said conductor includes:
a third conductor wire directly connecting said second main electrodes of said plurality of switching elements with each other.

7. The semiconductor device according to claim 6, wherein
said second wiring pattern extends along the direction of arrangement of said plurality of switching elements,
said plurality of first conductor wires are arranged in a direction substantially perpendicular to said direction of arrangement, and
said third conductor wire is arranged along said direction of arrangement.

8. The semiconductor device according to claim 7, wherein
said third conductor wire is connected with said second main electrodes of said plurality of switching elements on portions farther from said second wiring pattern than said first ends of said plurality of first conductor wires.

9. The semiconductor device according to claim 2, further comprising:
a fourth wiring pattern arranged on said main surface,
a plurality of fourth conductor wires having first ends connected to control electrodes of said plurality of switching elements and second ends connected to said fourth wiring pattern, and
a voltage clamping element having a first end connected to said third wiring pattern and a second end connected to said fourth wiring pattern.

10. A semiconductor device comprising:
a substrate having a main surface;
a first wiring pattern arranged on said main surface;
a plurality of switching elements arranged on said first wiring pattern so that first main electrodes thereof are electrically connected with each other;
a second wiring pattern arranged on said main surface;
a plurality of first conductor wires having first ends connected to second main electrodes of said plurality of switching elements and second ends connected to said second wiring pattern;
an external terminal connected to said second wiring pattern for electrically connecting said second main electrodes of said plurality of switching elements with the exterior through said second wiring pattern; and
a voltage clamping element electrically connected between control electrodes and said second main electrodes of said plurality of switching elements.

11. A semiconductor device comprising:
a substrate having a main surface;
a first wiring pattern arranged on said main surface;
a plurality of switching elements arranged on said first wiring pattern so that first main electrodes are electrically connected with each other;
a second wiring pattern arranged on said main surface to extend along the direction of arrangement of said plurality of switching elements;
a plurality of first conductor wires having first ends connected to second main electrodes thereof of said plurality of switching elements and second ends connected to said second wiring pattern;
an external terminal connected to said second wiring pattern for electrically connecting said second main electrodes of said plurality of switching elements with the exterior through said second wiring pattern;
a plurality of diodes, provided in the same number as said plurality of switching elements, arranged on said first wiring pattern so that first electrodes thereof are electrically connected with each other and arranged between said plurality of switching elements and said second wiring pattern to be adjacent to said plurality of switching elements in one-to-one correspondence;
a plurality of second conductor wires having first ends connected to second electrodes of said plurality of diodes and second ends connected to said second wiring pattern; and
a plurality of third conductor wires having first ends connected to said second main electrodes of said plurality of switching elements, intermediate potions connected to said second electrodes of at least part of said plurality of diodes and second ends connected to said second wiring pattern thereby electrically connecting all said second main electrodes of said plurality of switching elements with each other without through said second wiring pattern.

12. The semiconductor device according to any of claim 1, wherein
said second wiring pattern extends along the direction of arrangement of said plurality of switching elements,
said second wiring pattern is formed with a slit extending along said direction of arrangement so as to leave a coupling portion on the side of a first end of said direction of arrangement while as to leave no coupling portion on the side of a second end,
said second ends of said plurality of first conductor wires are connected to said second wiring pattern on a first portion closer to said plurality of switching elements than said slit, and
said external terminal is connected to said second wiring pattern on said coupling portion on the side of said first end,
said semiconductor device further comprising:
another external terminal connected to said second wiring pattern on the side of said second end in a second portion farther from said plurality of switching elements than said slit for electrically connecting said second main electrodes of said plurality of switching elements with the exterior through said second wiring pattern.

13. The semiconductor device according to claim 10, wherein
said second wiring pattern extends along the direction of arrangement of said plurality of switching elements,
said second wiring pattern is formed with a slit extending along said direction of arrangement so as to leave a coupling portion on the side of a first end of said direction of arrangement while as to leave no coupling portion on the side of a second end,
said second ends of said plurality of first conductor wires are connected to said second wiring pattern on a first portion closer to said plurality of switching elements than said slit, and
said external terminal is connected to said second wiring pattern on said coupling portion on the side of said first end,
said semiconductor device further comprising:
another external terminal connected to said second wiring pattern on the side of said second end in a second portion farther from said plurality of switching elements than said slit for electrically connecting said second main electrodes of said plurality of switching elements with the exterior through said second wiring pattern.

14. The semiconductor device according to claim 11, wherein
said second wiring pattern extends along the direction of arrangement of said plurality of switching elements,
said second wiring pattern is formed with a slit extending along said direction of arrangement so as to leave a coupling portion on the side of a first end of said direction of arrangement while as to leave no coupling portion on the side of a second end,
said second ends of said plurality of first conductor wires are connected to said second wiring pattern on a first portion closer to said plurality of switching elements than said slit, and
said external terminal is connected to said second wiring pattern on said coupling portion on the side of said first end,
said semiconductor device further comprising:
another external terminal connected to said second wiring pattern on the side of said second end in a second portion farther from said plurality of switching elements than said slit for electrically connecting said second main electrodes of said plurality of switching elements with the exterior through said second wiring pattern.

15. The semiconductor device according to claim 12, further comprising:
a fifth conductor wire having a first end connected to said first portion and a second end connected to said second portion.

16. The semiconductor device according to claim 1, wherein
each of said plurality of switching elements is an insulated gate switching element.

17. The semiconductor device according to claim 10, wherein
each of said plurality of switching elements is an insulated gate switching element.

18. The semiconductor device according to claim 11, wherein
each of said plurality of switching elements is an insulated gate switching element.
